(19) United States
(12) Patent Application Publication
(10) Pub. No.: US 2008/0298230 A1
(43) Pub. Date: Dec. 4, 2008

(54) Scheduling of workloads in a distributed compute environment

(76) Inventors: Siegfried J. Luft, Vancouver (CA); Jonathan Back, Vancouver (CA)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/809,344

(22) Filed: May 30, 2007

(51) Int. Cl. G01R 31/08

(52) U.S. Cl. 370/219

(57) ABSTRACT

A method of workload scheduling in a distributed compute environment includes assigning a subscriber of a network service to a first compute node instance (“CNI”) of a plurality of CNIs within a network node interposed between the subscriber and a provider of the network service. The subscriber traffic associated with the subscriber is processed at the first CNI. Subscriber specific data is generated at the first CNI related to the subscriber traffic. The subscriber specific data is then backed up to a second CNI of the network node that is designated as a standby CNI that will process the subscriber traffic if the first CNI fails.

### TECHNICAL FIELD

This disclosure relates generally to workload distribution in a distributed compute environment, and in particular but not exclusively, relates to workload distribution in a distributed compute environment of a network service node.

### BACKGROUND INFORMATION

The Internet is becoming a fundamental tool used in our personal and professional lives on a daily basis. As such, the bandwidth demands placed on network elements that underpin the Internet are rapidly increasing. In order to feed the seemingly insatiable hunger for bandwidth, parallel processing techniques have been developed to scale compute power in a cost effective manner.

As our reliance on the Internet deepens, industry innovators are continually developing new and diverse applications for providing a variety of services to subscribers. However, supporting a large diversity of services and applications using parallel processing techniques within a distributed compute environment introduces a number of complexities. One such complexity is to ensure that all available compute resources in the distributed environment are efficiently shared and effectively deployed. Ensuring efficient sharing of distributed resources requires scheduling workloads amongst the distributed resources in an intelligent manner so as to avoid situations where some resources are overburdened, while others lay idle.

FIG. 1 illustrates a modern metro area network 100 for providing network services to end users or subscribers. Metro area network 100 is composed of two types of networks: a core network 102 and one of more access networks 106. Core network 102 communicates data traffic from one or more service providers 104A-104N in order to provide services to one or more subscribers 108A-108M. Services supported by the core network 102 include, but are not limited to, (1) a branded service, such as a Voice over Internet Protocol (VoIP), from a branded service provider; (2) a licensed service, such as Video on Demand (VoD) or Internet Protocol Television (IPTV), through a licensed service provider and (3) traditional Internet access through an Internet Service Provider (ISP).

Core network 102 may support a variety of protocols (Synchronous Optical Networking (SONET), Internet Protocol (IP), Packet over SONET (POS), Dense Wave Division Multiplexing (DWDM), Border Gateway Protocol (BGP), etc.) using various types of equipment (core routers, SONET add-drop multiplexers, DWDM equipment, etc.). Furthermore, core network 102 communicates data traffic from the service providers 104A-104N to access network(s) 106 across link(s) 112. In general, link(s) 112 may be a single optical, copper or wireless link or may comprise several such optical, copper or wireless link(s).

On the other hand, the access network(s) 106 complements core network 102 by aggregating the data traffic from the subscribers 108A-108M. Access network(s) 106 may support data traffic to and from a variety of types of subscribers 108A-108M, (e.g. residential, corporate, mobile, wireless, etc.). Although access network(s) 106 may not comprise of each of the types of subscriber (residential, corporate, mobile, etc), access(s) network 106 will comprise at least one subscriber. Typically, access network(s) 106 supports thousands of subscribers 108A-108M. Access networks 106 may support a variety of protocols (e.g., IP, Asynchronous Transfer Mode (ATM), Frame Relay, Ethernet, Digital Subscriber Line (DSL), Point-to-Point Protocol (PPP), PPP over Ethernet (PPPoE), etc.) using various types of equipment (Edge routers, Broadband Remote Access Servers (BRAS), Digital Subscriber Line Access Multiplexers (DSLAM), Switches, etc). Access network(s) 106 uses a subscriber policy manager(s) 110 to set policies for individual ones and/or groups of subscribers. Policies stored in a subscriber policy manager(s) 110 allow subscribers access to different ones of the service providers 104A-N. Examples of subscriber policies are bandwidth limitations, traffic flow characteristics, amount of data, allowable services, etc.

Subscriber traffic flows across access network(s) 106 and core network 102 in data packets. A data packet (also known as a “packet”) is a block of user data with necessary address and administration information attached, usually in a packet header and/or footer, which allows the data network to deliver the data packet to the correct destination. Examples of data packets include, but are not limited to, IP packets, ATM cells, Ethernet frames, SONET frames and Frame Relay packets. Typically, data packets having similar characteristics (e.g., common source and destination) are transmitted in a flow.

FIG. 2 represents the Open Systems Interconnect (OSI) model of a layered protocol stack 200 for transmitting data packets. Each layer installs its own header in the data packet being transmitted to control the packet through the network. The physical layer (layer 1) 202 is used for the physical signaling. The next layer, data link layer (layer 2) 204, enables transferring of data between network entities. The network layer (layer 3) 206 contains information for transferring variable length data packet between one or more networks. For example, IP addresses are contained in the network layer 206, which allows network devices (also commonly referred to a network elements) to route the data packet. Layer 4, the transport layer 208, provides transparent data transfer between end users. The session layer (layer 5) 210, provides the mechanism for managing the dialogue between end-user applications. The presentation layer (layer 6) 212 provides independence from difference in data representation (e.g. encryption, data encoding, etc.). The final layer is the application layer (layer 7) 212, which contains the actual data used by the application sending or receiving the packet. While most protocol stacks do not exactly follow the OSI model, it is commonly used to describe networks.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 (Prior Art) illustrates a typical metro area network configuration.

FIG. 2 (Prior Art) is a block diagram illustrating layers of the Open Systems Interconnect protocol stack.

FIG. 3 is a block diagram illustrating a demonstrative metro area network configuration including a service node to provide application and subscriber aware packet processing, in accordance with an embodiment of the invention.

FIG. 4 is a schematic diagram illustrating one configuration of a service node implemented using an Advanced Telecommunication and Computing Architecture chassis with full-mesh backplane connectivity, in accordance with an embodiment of the invention.

FIG. 5 is a functional block diagram illustrating traffic and compute blade architecture of a service node for supporting application and subscriber aware packet processing, in accordance with an embodiment of the invention.

FIG. 6 is a functional block diagram illustrating multi-level packet classification in a distributed compute environment, in accordance with an embodiment of the invention.

FIG. 7 is a block diagram illustrating subscriber assignment and workload scheduling in a distributed compute environment, in accordance with an embodiment of the invention.

FIG. 8 is a flow chart illustrating a process for scheduling workloads in a distributed compute environment, in accordance with an embodiment of the invention.

FIG. 9 is a block diagram illustrating subscriber distributions during a failover event of a distributed compute environment, in accordance with an embodiment of the invention.

FIG. 10 includes two state diagrams illustrating failover events in a distributed compute environment, in accordance with an embodiment of the invention.

FIG. 11 is a block diagram illustrating subscriber redistribution in a distributed compute environment, in accordance with an embodiment of the invention.

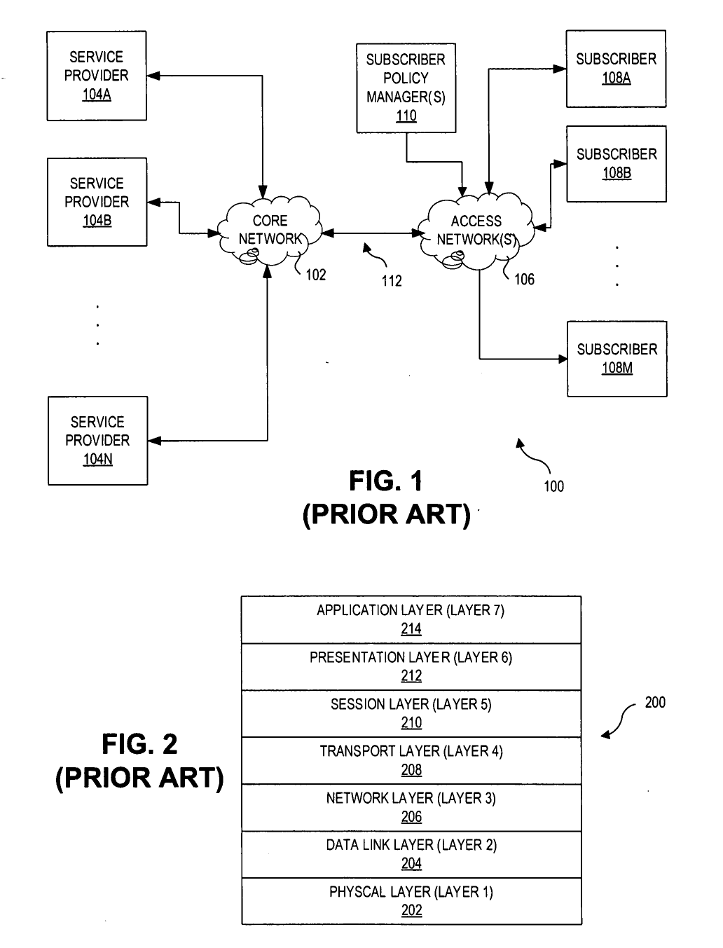

### DETAILED DESCRIPTION

Embodiments of a system and method for scheduling workloads in a distributed compute environment are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

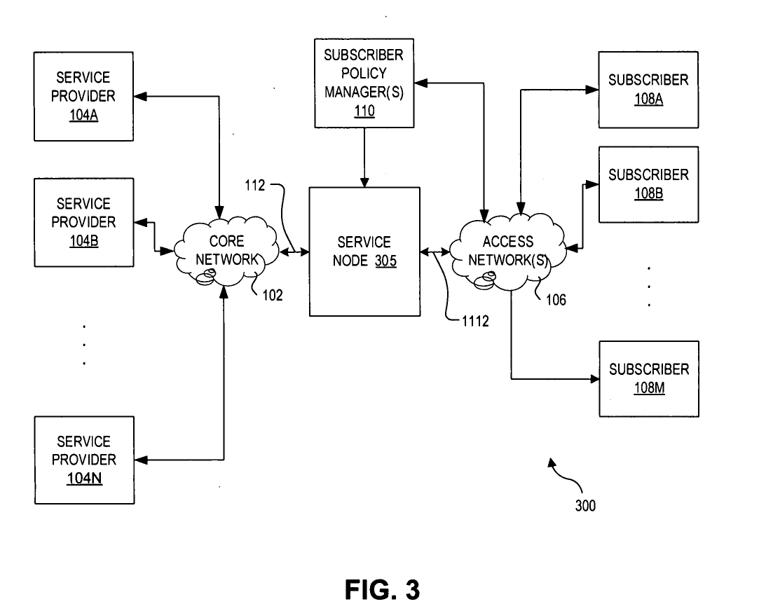

FIG. 3 is a block diagram illustrating a demonstrative metro area network 300 including a service node 305 to provide application and subscriber aware packet processing, in accordance with an embodiment of the invention. Metro area network 300 is similar to metro area network 100 with the exception of service node 305 inserted at the junction between access network 106 and core network 102.

In one embodiment, service node 305 is an application and subscriber aware network element capable of implementing application specific policies on a per subscriber basis at line rates. For example, service node 305 can perform quality of service (“QoS”) tasks (e.g., traffic shaping, flow control, admission control, etc.) on a per subscriber, per application basis, while monitoring quality of experience (“QoE”) on a per session basis. To enable QoS and QoE applications for a variety of network services (e.g., VoD, VoIP, IPTV, etc.), service node 305 is capable of deep packet inspection all the way to the session and application layers of the OSI model. To provide this granularity of service to hundreds or thousands of unique subscribers requires leveraging parallel processing advantages of a distributed compute environment. To effectively provide these services at full line rates, further requires efficient scheduling and distribution of the workloads associated with subscribers across compute node instances of the distributed compute environment, discussed in detail below.

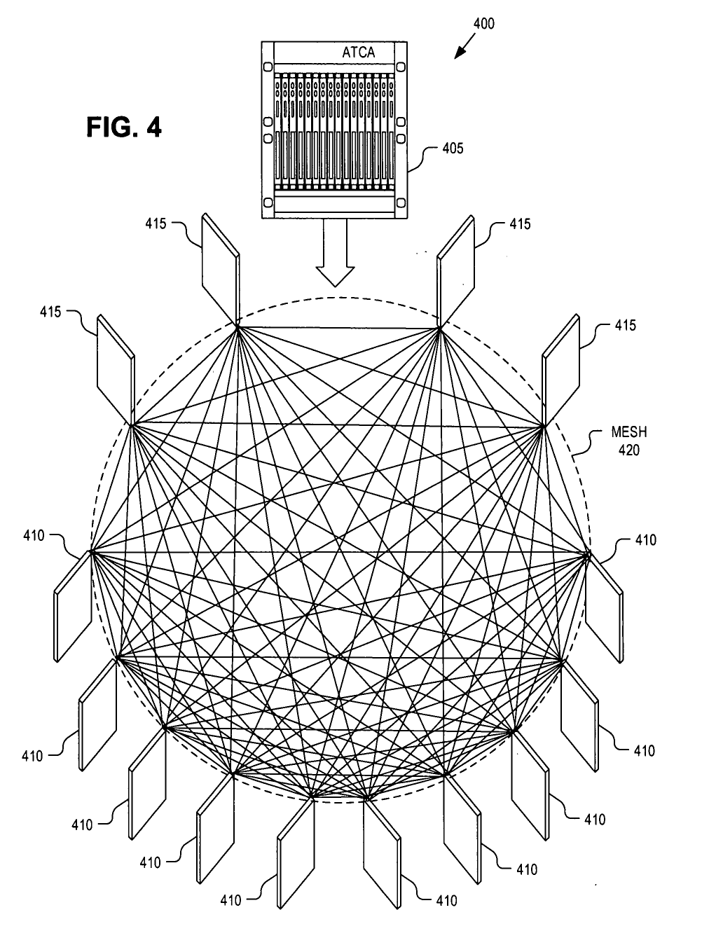

FIG. 4 is a schematic diagram illustrating a service node 400 implemented using an Advanced Telecommunication and Computing Architecture (“ATCA”) chassis with full-mesh backplane connectivity, in accordance with an embodiment of the invention. Service node 400 is one possible implementation of service node 305.

In the configuration illustrated in FIG. 4, an ATCA chassis 405 is fully populated with 14 ATCA blades—10 traffic blades 410 and 4 compute blades 415—each installed in a respective chassis slot. In an actual implementation, chassis 405 may be populated with less blades or may include other types or combinations of traffic blades 410 and compute blades 415. Furthermore, chassis 405 may include slots to accept more or less total blades in other configurations (e.g., horizontal slots). As depicted by interconnection mesh 420, each blade is communicatively coupled with every other blade under the control of fabric switching operations performed by each blade's fabric switch. In one embodiment, mesh interconnect 420 provides a 10 Gbps connection between each pair of blades, with an aggregate bandwidth of 280 Gbps. It is noted that the ATCA environment depicted herein is merely illustrative of one modular board environment in which the principles and teachings of the embodiments of the invention described herein may be applied. In general, similar configurations may be deployed for other standardized and proprietary board environments, including but not limited to blade server environments.

In the illustrated embodiments, service node 400 is implemented using a distributed architecture, wherein various processor and memory resources are distributed across multiple blades. To scale a system, one simply adds another blade. The system is further enabled to dynamically allocate processor tasks, and to automatically perform failover operations in response to a blade failure or the like. Furthermore, under an ATCA implementation, blades may be hot-swapped without taking the system down, thus supporting dynamic scaling.

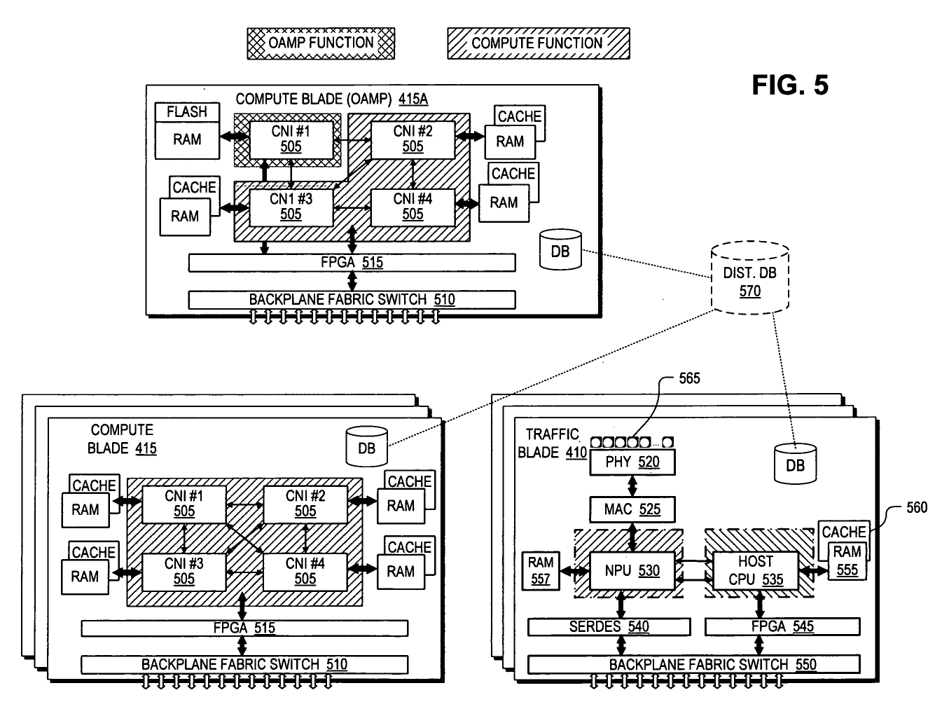

FIG. 5 is a functional block diagram illustrating demonstrative hardware architecture of traffic blades 410 and compute blades 415 of service node 400, in accordance with an embodiment of the invention. The illustrated embodiment of service node 400 uses a distinct architecture for traffic blades 410 versus compute blades 415, while at least one of compute blades 415 (e.g., compute blade 415A) is provisioned to perform operations, administration, maintenance and provisioning (“OAMP”) functionality.

Compute blades 415 each employ four compute node instances (“CNIs”) 505. CNIs 505 may be implemented using separate processors or processor chips employing multiple processor cores. For example, in the illustrated embodiment of FIG. 5, each of CNI 505 is implemented via an associated symmetric multi-core processor. Each CNI 505 is enabled to communicate with other CNIs via an appropriate interface, such as for example, a “Hyper Transport” (HT) interface. Other native (standard or proprietary) interfaces between CNIs 505 may also be employed.

As further depicted in FIG. 5, each CNI 505 is allocated various memory resources, including respective RAM. Under various implementations, each CNI 505 may also be allocated an external cache, or may provide one or more levels of cache on-chip.

Each Compute blade 415 includes an interface with mesh interconnect 420. In the illustrated embodiment of FIG. 5, this is facilitated by a backplane fabric switch 510, while a field programmable gate array (“FPGA”) 515 containing appropriate programmed logic is used as an intermediary component to enable each of CNIs 505 to access backplane fabric switch 510 using native interfaces. In the illustrated embodiment, the interface between each of CNIs 505 and the FPGA 515 comprises a system packet interface (“SPI”), while the interface between FPGA 515 and backplane fabric switch 510 comprises a Broadcom HiGig™ interface. It is noted that these interfaces are mere examples, and that other interfaces may be employed.

In addition to local RAM, the CNI 505 associated with the OAMP function (depicted in FIG. 5 as CNI #1 of compute blade 415A) is provided with a local non-volatile store (e.g., flash memory). The non-volatile store is used to store persistent data used for the OAMP function, such as provisioning information and logs. In compute blades 415 that do not support the OAMP function, each CNI 505 is provided with local RAM and a local cache.

FIG. 5 further illustrates a demonstrative architecture for traffic blades 410. Traffic blades 410 include a PHY block 520, an Ethernet MAC block 525, a network processor unit (NPU) 530, a host processor 535, a serializer/deserializer (“SERDES”) interface 540, an FPGA 545, a backplane fabric switch 550, RAM 555 and 557 and cache 560. Traffic blades 410 further include one or more I/O ports 565, which are operatively coupled to PHY block 520. Depending on the particular use, the number of I/O ports 565 may vary from 1 to N ports. For example, under one traffic blade type a 10×1 Gigabit Ethernet (GigE) port configuration is provided, while for another type a 1×10 GigE port configuration is provided. Other port number and speed combinations may also be employed.

One of the operations performed by traffic blade 410 is packet identification/classification. A multi-level classification hierarchy scheme is implemented for this purpose. Typically, a first level of classification, such as a 5 or 6 tuple signature classification scheme, is performed by NPU 530. Additional classification operations in the classification hierarchy may be required to fully classify a packet (e.g., identify an application flow type). In general, these higher-level classification operations may be performed by the traffic blade's host processor 535 and/or compute blades 415 via interception or bifurcation of packet flows.

Typically, NPUs are designed for performing particular tasks in a very efficient manner. These tasks include packet forwarding and packet classification, among other tasks related to packet processing. NPU 530 includes various interfaces for communicating with other board components. These include an Ethernet MAC interface, a memory controller (not shown) to access RAM 557, Ethernet and PCI interfaces to communicate with host processor 535, and an XGMII interface. SERDES interface 540 provides the interface between XGMII interface signals and HiGig signals, thus enabling NPU 530 to communicate with backplane fabric switch 550. NPU 530 may also provide additional interfaces to interface with other components (not shown).

Similarly, host processor 535 includes various interfaces for communicating with other board components. These include the aforementioned Ethernet and PCI interfaces to communicate with NPU 530, a memory controller (on-chip or off-chip—not shown) to access RAM 555, and a pair of SPI interfaces. FPGA 545 is employed as an interface between the SPI interface signals and the HiGig interface signals.

Host processor 535 is employed for various purposes, including lower-level (in the hierarchy) packet classification, gathering and correlation of flow statistics, and application of traffic profiles. Host processor 535 may also be employed for other purposes. In general, host processor 535 will comprise a general-purpose processor or the like, and may include one or more compute cores. In one embodiment, host processor 535 is responsible for initializing and configuring NPU 530 (e.g., via network booting).

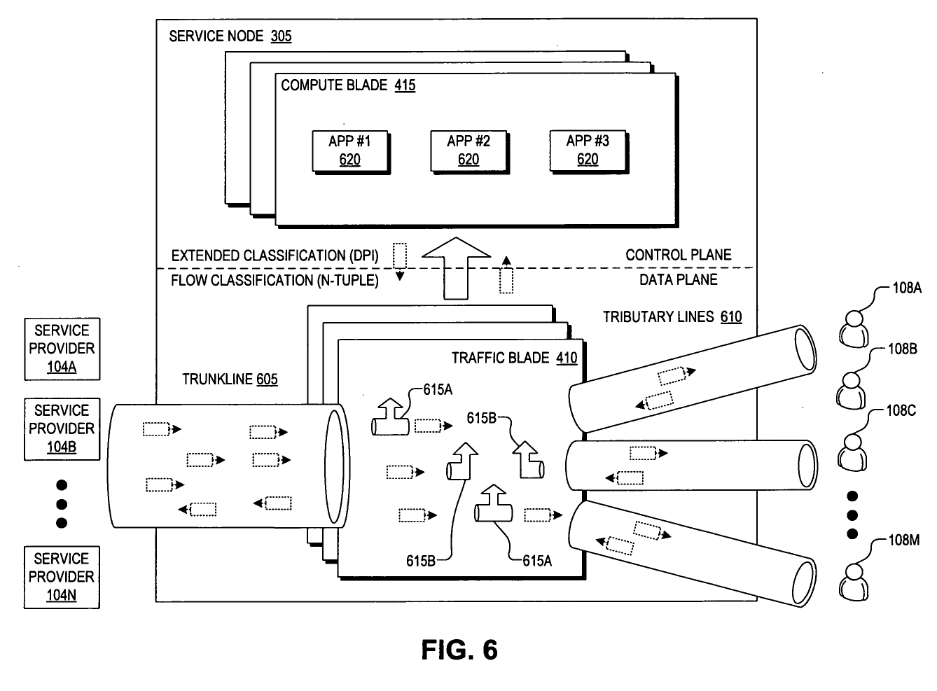

FIG. 6 is a functional block diagram illustrating a multi-level packet classification scheme executed within service node 305, in accordance with an embodiment of the invention.

During operation, packets arrive and depart service node 305 along trunkline 605 from/to service providers 104 and arrive and depart service node 305 along tributary lines 610 from/to subscribers 108. Upon entering traffic blades 410, access control is performed by comparing Internet protocol (“IP”) header fields against an IP access control list (“ACL”) to determine whether the packets have permission to enter service node 305. Access control may be performed by a hardware abstraction layer (“HAL”) of traffic blades 410. If access is granted, then service node 305 will proceed to classify each arriving packet. Packet classification includes matching upon N fields (or N-tuples) of a packet to determine which classification rule to apply and then executing an action associated with the matched classification rule.

Traffic blades 410 perform flow classification in the data plane as a prerequisite to packet forwarding and/or determining whether extended classification is necessary by compute blades 415 in the control plane. In one embodiment, flow classification involves 6-tuple classification performed on the TCP/IP packet headers (i.e., source address, destination address, source port, destination port, protocol field, and differentiated service code point). Based upon the flow classification, traffic blades 410 may simply forward the traffic, bifurcate the traffic, or intercept the traffic. If a traffic blade 410 determines that a bifurcation filter 615A has been matched, the traffic blade 410 will generate a copy of the packet that is sent to one of compute blades 415 for extended classification, and forward the original packet towards its destination. If a traffic blade 410 determines that an interception filter 615B has been matched, the traffic blade 410 will divert the packet to one of compute blades 415 for extended classification prior to forwarding the packet to its destination.

Compute blades 415 perform extended classification via deep packet inspection (“DPI”) to further identify a classification rule or rules to apply to the received packet. Extended classification may include inspecting the bifurcated or intercepted packets at the application level (e.g., regular expression matching, bitwise matching, etc.) and performing additional processing by applications 620. This application level classification enables applications 620 to apply application specific rules to the traffic. These application specific rules can be stateful rules that track a protocol exchange and even modify match criteria in real-time based upon the state reached by the protocol exchange. For example, application #1 may be a VoIP QoE application for monitoring the quality of experience of a VoIP service, application #2 may be a VoD QoE application for monitoring the quality of experience of a VoD service, and application #3 may be an IP filtering application providing uniform resource locator (“URL”) filtering to block undesirable traffic, an email filter, a parental control filter on an IPTV service, or otherwise. It should be appreciated that compute blades 415 may execute any number of network applications 620 for implementing a variety of networking functions.

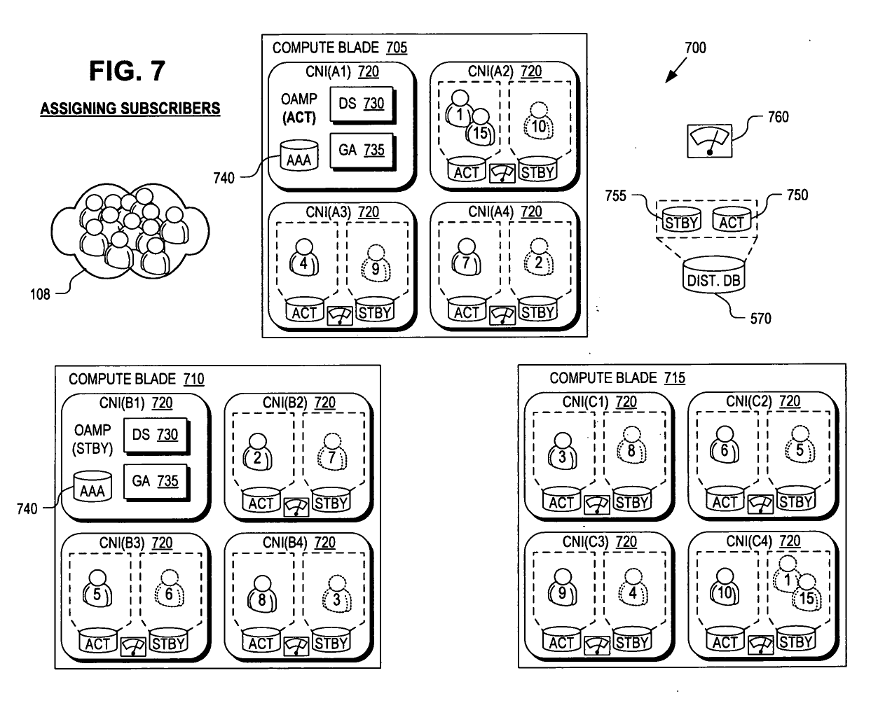

FIG. 7 is a block diagram illustrating subscriber assignment and workload scheduling in a distributed compute environment 700, in accordance with an embodiment of the invention. The illustrated embodiment of distributed compute environment 700 includes three compute blades 705, 710, and 715, each including four CNIs 720 (e.g., CNIs A1-A4, CNIs B1-B4, CNIs C1-C4). Compute blades 705 represent a possible implementation of compute blades 415 and CNIs 720 represent a possible implementation of CNIs 505. It should be appreciated that distributed compute environment 700 may include more or less compute blades 705 and each compute blade 705 may itself include more or less CNIs 720.

CNIs 720 provide a distributed compute environment for executing applications 620. In particular, CNI A1 is assigned as the active OAMP manager and is provisioned with OAMP related software for managing/provisioning all other CNIs 720 within service node 305. Similarly, CNI B1 is assigned as a standby OAMP manager and is also provisioned with OAMP related software. CNI B1 functions as a failover backup to CNI A1 to takeover active OAMP managerial status in the event CNI A1 or compute blade 705 fails. CNIs 720 further include local instances of a distributed scheduler agent 730 and a global arbitrator agent 735 (only the OAMP instances are illustrated; however, each CNI 720 may include a slave instance of global arbitrator which all report to the master instance running on the OAMP CNI). In one embodiment, CNIs A1 and B1 may also include an authorization, authentication, and accounting (“AAA”) database 740, although AAA database 740 may also be remotely located outside of service node 305. Each CNI 720 includes a local instance of distributed database 570. In particular, with the possible exception of CNI A1 and CNI B1, each CNI 720 includes an active portion 750 and a standby portion 755 within their local instance of distributed database 570. Finally, each CNI 720, with the exception of CNI A1 and CNI B1, may also include a local instance of a metric collection agent 760. In one embodiment, metrics collection agent 760 may be subsumed within global arbitrator 735 as a sub-feature thereof. In one embodiment, each CNI 720 may include multiple metric collection agents 760 for collecting and report standardized metrics (e.g., number of active session, bandwidth allocation per subscriber, etc.) or each application 620 may collect and report its own application specific metrics.

Global arbitrator 735 collects and maintains local and global resource information in real-time for service node 305. Global Arbitrator has access to a “world view” of available resources and resource consumption in each CNI 720 across all compute blades 705, 710, and 715. Global arbitrator 735 is responsible for monitoring applications 620 as well as gathering metrics (e.g., CPU usage, memory usage, other statistical or runtime information) on a per application basis and propagating this information to other instances of global arbitrator 735 throughout service node 305. Global arbitrator 735 may maintain threshold alarms to ensure that applications 620 do not exceed specific limits, can notify distributed scheduler 730 of threshold violations, and can passively, or forcibly, restart errant applications 620.

Distributed Scheduler 730 is responsible for load balancing resources across compute blades 705 and CNIs 720. In particular, distributed scheduler 730 is responsible for assigning subscribers 108 to CNIs 720, and in some embodiments, also assigns which CNI 720 will backup a subscriber 108. Assigning a particular subscriber 108 to a particular CNI 720 determines which CNI 720 will assume the workload associated with processing the traffic of the particular subscriber 108. The particular CNI 720 to which a subscriber 108 has been assigned is referred to as that subscriber's “active CNI.” Each subscriber 108 is also assigned a “standby CNI,” which is responsible for backing up subscriber specific data generated by the active CNI while processing the subscriber's traffic.

In one embodiment, distributed database 570 is responsible for storing, maintaining, and distributing the subscriber specific data generated by applications 620 in connection with each subscriber 108. During operation, applications 620 may write subscriber specific data directly into active portion 750 of its local instance of distributed database 570. Thereafter, distributed database 570 backs up the subscriber specific data to the appropriate standby portion 755 residing on a different CNI 720. In this manner, when a particular CNI 720 goes offline or otherwise fails, the standby CNIs associated with each subscriber 108 will transition the subscriber backups to an active status, thereby becoming the new active CNI for each affected subscriber 108.

As previously mentioned, distributed scheduler 730 is responsible for assigning subscribers 108 to CNIs 720. Accordingly, distributed scheduler 730 has knowledge of each subscriber 108 and to which CNI 720 each subscriber 108 has been assigned. When assigning a new subscriber 108 to one of CNIs 720, distributed scheduler 730 may apply an intelligent scheduling algorithm to evenly distribute workloads across CNIs 720. In one embodiment, distributed scheduler 730 may refer to the metrics collected by global arbitrator 735 to determine which CNI 720 has excess capacity in terms of CPU and memory consumption. Distributed scheduler 730 may apply a point system when assigning subscribers 108 to CNIs 720. This point system may assign varying work points or work modicums to various tasks that will be executed by applications 620 in connection with a particular service and use this point system in an attempt to evenly balance workloads.

When calculating workloads, “non-active” workloads may also be taken into account. For example, if a subscriber is assigned to a particular CNI 720 and this subscriber subscribers to 32 various network services (but NONE actually currently active), then this subscriber may not be ignored when calculating the load of the particular CNI. A weighting system can be applied where inactive subscribers have their “points” reduced if they remain inactive for periods of time (possibly incrementally increasing the reduction). Therefore, highly active subscribers affect the system to a greater extent than subscribers that have been inactive for weeks. This weighting system could, of course, lead to over subscription of a CNI resource—but would likely yield greater utilization of the CNI resources on average.

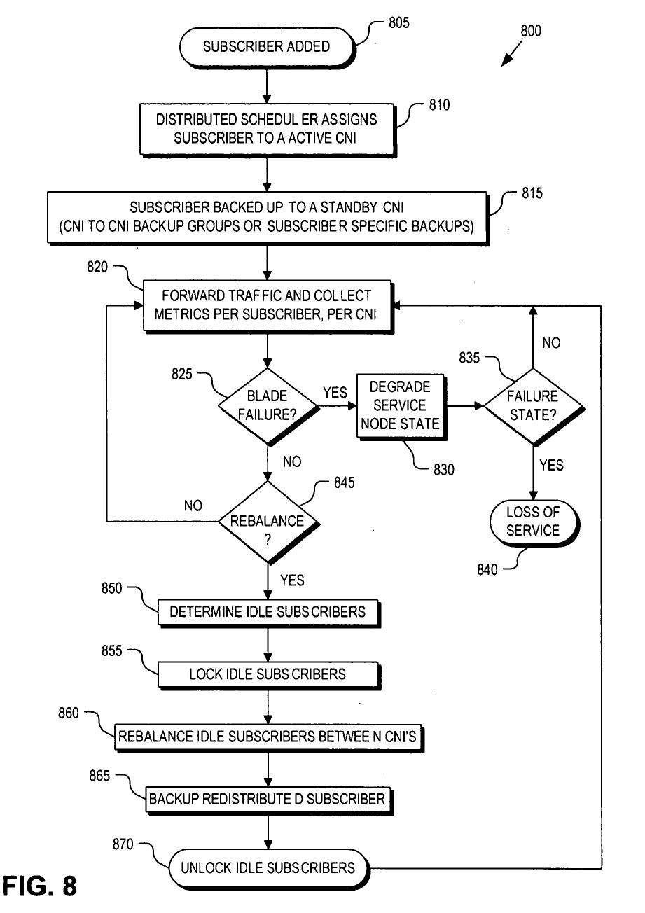

FIG. 8 is a flow chart illustrating a process 800 for scheduling workloads in distributed compute environment 700, in accordance with an embodiment of the invention. The order in which some or all of the process blocks appear in process 800 should not be deemed limiting. Rather, one of ordinary skill in the art having the benefit of the present disclosure will understand that some of the process blocks may be executed in a variety of orders not illustrated or even in parallel.

In a process block 805, a new subscriber 108 is added to service node 305. The new subscriber 108 may be added in response to the subscriber logging onto his/her network connection for the first time, requesting a new service for the first time, in response to a telephonic request to a service provider representative, or otherwise. In one embodiment, the new subscriber is added to service node 305 when account information for the subscriber is added to AAA database 740. Upon receiving the request to add the new subscriber 108, distributed scheduler 730 may refer to AAA database 740 to determine the services, privileges, priority, etc. to be afforded the new subscriber.

In a process block 810, distributed scheduler 730 assigns the new subscriber 108 to an active CNI chosen from amongst CNIs 720. Distributed scheduler 730 may consider a variety of factors when choosing which CNI 720 to assign the new subscriber 108. These factors may include the particular service requested, which CNIs 720 are provisioned with applications 620 capable of supporting the requested service, the prevailing workload distribution, the historical workload distribution, as well as other factors.

By assigning the new subscriber 108 to an active CNI, distributed scheduler 730 is selecting which CNI 720 will be responsible for processing the subscriber traffic associated with the new subscriber 108. For example, in the case of subscriber 15, distributed scheduler 730 has assigned subscriber 15 to CNI A2 on compute blade 705. During operation, applications 620 executing on CNI A2 will write subscriber specific data related to traffic from subscriber 15 into active portion 750 of the instance of distributed database 570 residing on CNI A2.

In a process block 815, the subscriber specific data written into active portion 750 of distributed database 570 is backed up to a corresponding standby portion 755 residing on another CNI 720, referred to as the standby CNI for the particular subscriber. In one embodiment, the standby CNI for a particular subscriber is always located on a different compute blade than the subscriber's active CNI. In the example of subscriber 15, the standby CNI is CNI C4 on compute blade 715. In one embodiment, replication of the subscriber specific data is carried out under control of distributed database 570, itself.

Selection of a standby CNI for a particular subscriber 108 may be designated via a CNI-to-CNI group backup technique or a subscriber specific backup technique. If the CNI-to-CNI group backup technique is implemented, then CNIs 720 are associated in pairs for the sake of backing up subscriber specific data. In other words, the paired CNIs 720 backup all subscribers assigned to each other. For example, FIG. 7 illustrates subscribers 1 and 15 currently assigned to CNI A2 as their active CNI, both of which are backed up to CNI C4 as their standby CNI. Correspondingly, subscriber 10 is assigned to CNI C4 as its active CNI, and backed up to CNI A2 as its standby CNI. The CNI-to-CNI group backup technique is effectuated by distributed database 570 forming fixed backup associations between CNI pairs and backing up all subscribers between the paired CNIs.

If the subscriber specific backup technique is implemented, then distributed scheduler 730 individually selects both the active CNI and the standby CNI for each subscriber 108. While the subscriber specific backup technique may require additional managerial overhead, it provides greater flexibility to balance and rebalance subscriber backups and provides more resilient fault protection (discussed in detail below). Once distributed scheduler 730 notifies distributed database 570 which CNI 720 will operate as the standby CNI for a particular subscriber 108, it is up to distributed database 570 to oversee the actual replication of the subscriber specific data in real-time.

In a process block 820, subscriber traffic is received at service node 305 and forwarded onto its destination. In connection with receiving and processing subscriber traffic, filters 615A and 615B identify pertinent traffic and either bifurcate or intercept the traffic for delivery to applications 620 for extended classification and application-level related processing. In one embodiment, one or more of applications 620 collect metrics on a per subscriber, per CNI basis. These metrics may include statistical information related to subscriber activity, subscriber bandwidth consumption, QoE data per subscriber, etc.

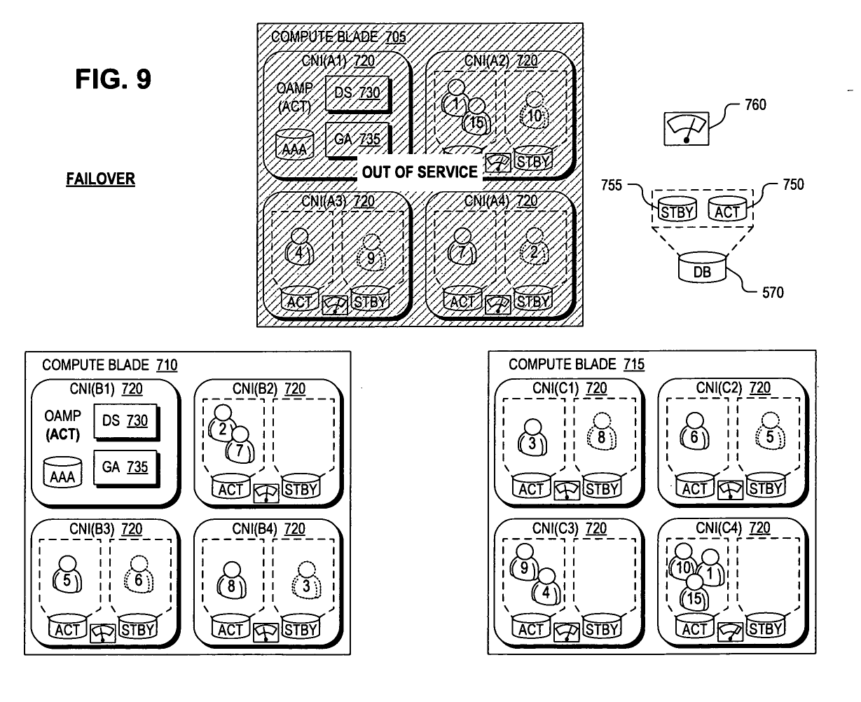

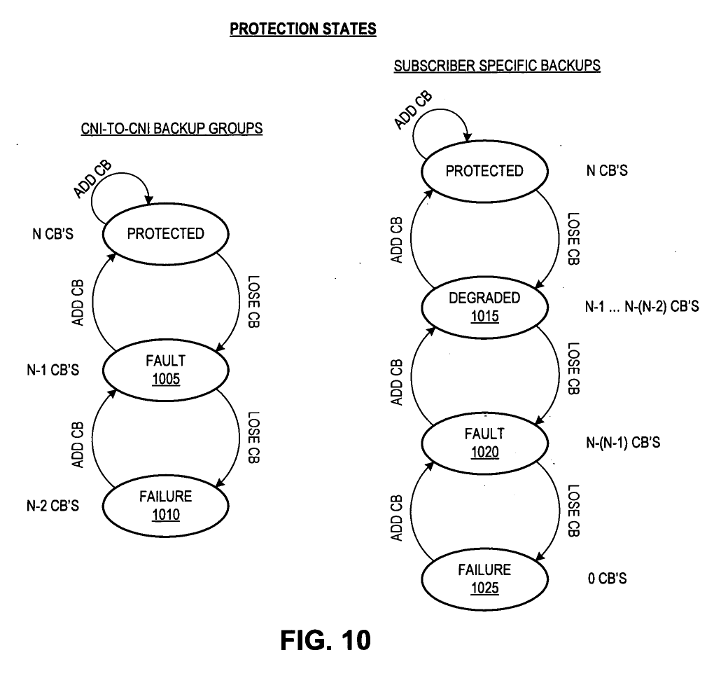

In a decision block 825, if one of compute blades 705, 710, or 715 fails, then the operational state of service node 305 is degraded (process block 830). If the subscriber specific data is backed up via the CNI-to-CNI backup technique, then service node 305 enters a fault state 1005 (see FIG. 10). Fault state 1005 represents a state of operation of service node 305 where no subscriber 108 has lost service, but where one or more subscribers 108 are no longer backed up to a standby CNI. This is a result of fixed associations between active and standby CNIs under the CNI-to-CNI backup groups. With reference to FIG. 9, if compute blade 705 fails, then the backups of subscribers 1, 4, 7, and 15 are activated on their standby CNIs. In other words, subscriber 15 is moved from the standby status on CNI C4 of compute blade 715 to the active status. However, since the backup association between CNI A2 and CNI C4 is fixed, subscriber 15 is no longer backed up. Likewise, subscribers 1, 4, and 7 are no longer backed up. If service node 305 were to lose any additional compute blades (decision block 825), service node 305 would enter a failure state 1010 (decision block 835) and begin dropping subscribers 108 (process block 840).

Returning to process block 825, if subscriber specific data is backed up via the more fault tolerant subscriber specific backup technique, then service node 305 enters a degraded state 1015. However, since the backup associations are not fixed under the subscriber specific backup technique, distributed scheduler 730 can designate new standby CNIs for the subscribers affected by the failed compute blade. Service node 305 can continue to lose compute blades (decision block 825) and remain in degraded state 1015 until there is only one remaining compute blade. Upon reaching a state with only one functional compute blade, service node 305 enters a fault state 1020 (see FIG. 10). While operating in fault state 1020, service node 305 has not yet dropped any subscribers 108; however, subscribers 108 are no longer backed up. Once in fault state 1020, service node 305 is no longer capable of backing up subscriber 108, since only a single compute blade remains functional. If the last functional compute blade fails, then service node 305 would enter a failure state 1025 (decision block 835) and drop subscriber traffic (process block 840).

Returning to decision block 825, if the compute blade that fails includes the active OAMP CNI (e.g., compute blade 705 as illustrated in FIG. 9), then the standby OAMP CNI is transitioned to active status. Accordingly, as illustrated in FIG. 9, CNI B1 of compute blade 710 is identified as the active OAMP CNI. Since distributed scheduler 730, global arbitrator 735, and distributed database 570 are distributed entities having local instances on each CNI 720, the failover is seamless with little or not interruption from the subscribers' perspective.

Continuing to a decision block 845, distributed scheduler 730 determines whether to rebalance the subscriber traffic workload amongst CNIs 720. In one embodiment, distributed scheduler 730 makes this decision based upon the feedback information collected by global arbitrator 735. As discussed above, distributed scheduler 730 assigns subscribers 108 to CNIs 720 based upon assumptions regarding the anticipated workloads associated with each subscriber 108. Global arbitrator 735 monitors the actual workloads (e.g., CPU consumption, memory consumption, etc.) of each CNI 720 and provides this information to distributed scheduler 730. Based upon the feedback information from global arbitrator 735, distributed scheduler 730 can determine the validity of its original assumptions and make assignment alternations, if necessary. Furthermore, if one or more CNIs 720 fail, the workload distribution of the remaining CNIs 720 may become unevenly distributed, also calling for workload redistributions.

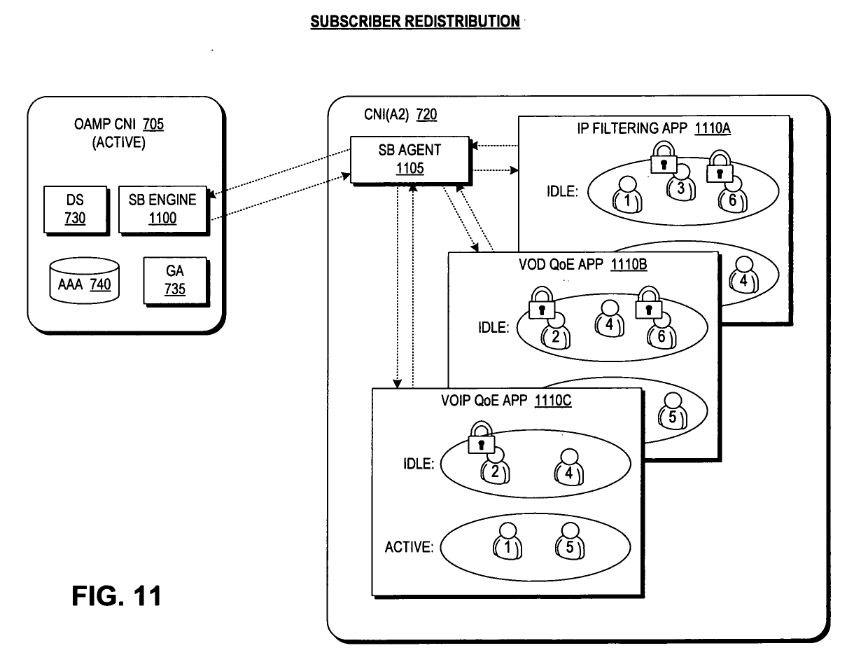

If distributed scheduler 730 determines a workload redistribution should be executed (decision block 845), process 800 continues to a process block 850. With reference to FIG. 11, in process block 850, distributed scheduler 730 determines which subscribers 108 are idle. Since idle subscribers are those subscribers 108 that do not have active or current service sessions (e.g., not currently utilizing a network service), the idle subscribers can be redistributed amongst CNIs 720 without interrupting service. In contrast, active subscribers are actively accessing a service and transferring an active subscribe to another CNI 720 may result in data loss or even temporary service interruption.

To identify idle subscribers 108, distributed scheduler 730 queries a sandbox engine 1100 executing on the OAMP CNI. In turn, sandbox engine 1100 communicates with instances of a sandbox agent 1105 distributed on each CNI 720 within service node 305. FIG. 11 illustrates three network applications executing on CNI A2—an IP filtering application 1110A, a VoD QoE application 1110B, and a VoIP QoE application 1110C (collectively applications 1110). Applications 1110 correspond to instances of applications 620. In one embodiment, each application 1110 is executed within an independent and isolated virtual machine (“VM”). Local instances of sandbox agent 1105 are responsible for starting, stopping, and controlling applications 1110 via their VMs. Upon receiving the idle subscriber query from sandbox engine 1100, sandbox agent 1105 will query each application 1110 executing on its CNI 720 and report back to sandbox engine 1100 executing on the OAMP CNI 720.

As illustrated in FIG. 11, subscribers 1, 4, and 5 are actively accessing at least one service and therefore are not currently available for redistribution. However, subscribers 2, 3, and 6 are currently idle, not accessing any of their permissive services. In a process block 855, idle subscribers 2, 3, and 6 are locked. Once locked, subscribers 2, 3, and 6 will be denied access to value added network services provided by network applications 620 should they attempted to access such services. However, the subscriber traffic should continue to ingress and egress service node 305 along the data plane. In some instances, the subscriber traffic may actually be denied access during re-balancing, such as in the example of security applications or monitoring applications. In a process block 860, distributed scheduler 730 redistributes the idle subscribers. In one embodiment, redistributing the idle subscribers includes reassigning idle subscribers assigned to overburdened CNIs 720 to under worked CNIs 720.

In a process block 865, the redistributed idle subscribers 108 are reassigned new standby CNIs for backup and their backups transferred via distributed database 570 to the corresponding standby CNI. Finally, in a process block 870, the redistributed subscribers 108 are unlocked to permit applications 1110 to commence processing subscriber traffic.

The processes explained above are described in terms of computer software and hardware. The techniques described may constitute machine-executable instructions embodied within a machine (e.g., computer) readable medium, that when executed by a machine will cause the machine to perform the operations described. Additionally, the processes may be embodied within hardware, such as an application specific integrated circuit (“ASIC”) or the like.

A machine-readable storage medium includes any mechanism that provides (i.e., stores and/or transmits) information in a form accessible by a machine (e.g., a computer, network device, personal digital assistant, manufacturing tool, any device with a set of one or more processors, etc.). For example, a machine-readable medium includes recordable/non-recordable media (e.g., read only memory (ROM), random access memory (RAM), magnetic disk storage media, optical storage media, flash memory devices, etc).

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A method of workload scheduling in a distributed compute environment, the method comprising:
assigning a subscriber of a network service to a first compute node instance (“CNI”) of a plurality of CNIs within a network node interposed between the subscriber and a provider of the network service;
processing subscriber traffic associated with the subscriber at the first CNI;
generating subscriber specific data at the first CNI related to the subscriber traffic; and
backing up the subscriber specific data to a second CNI of the network node, wherein the second CNI is designated as a standby CNI to process the subscriber traffic if the first CNI fails.

2. The method of claim 1, wherein the network service includes at least one of an Internet access service, a video-on-demand (“VoD”) service, a voice over Internet protocol (“VoIP”) service, or an Internet Protocol television (“IPTV”) service.

3. The method of claim 1, wherein the subscriber traffic comprises original subscriber traffic and wherein processing the subscriber traffic associated with the subscriber at the first CNI comprises:
executing at least one network application related to the network service on the first CNI;
replicating portions of the original subscriber traffic at the network node to generate replicated subscriber traffic;
forwarding the original subscriber traffic towards its destination; and
providing the replicated subscriber traffic to the at least one network application executing on the first CNI.

4. The method of claim 1, wherein processing the subscriber traffic associated with the subscriber at the first CNI comprises:
intercepting portions of the subscriber traffic at the network node;
forwarding intercepted portions of the subscriber traffic to the at least one network application executing on the first CNI for processing; and
forwarding the intercepted portions towards their destination after the processing.

5. The method of claim 3, wherein the at least one network application includes at least one quality of experience (“QoE”) application for monitoring the subscriber's QoE while using the network service and wherein the subscriber specific data comprises data generated by the at least one QoE application while monitoring the subscriber traffic.

6. The method of claim 1, wherein backing up the subscriber specific data to the second CNI of the network node comprises:
writing the subscriber specific data to a first instance of a distributed database residing on the first CNI, wherein the distributed database includes a plurality of instances each residing on one of the plurality of CNIs; and
replicating backup copies of the subscriber specific data to a second instance of the distributed database residing on the second CNI.

7. The method of claim 6,
wherein each of the plurality of instances of the distributed database includes an active portion and a standby portion,
wherein writing the subscriber specific data to the first instance of the distributed database comprises writing the subscriber specific data to the active portion of the first instance of the distributed database residing on the first CNI, and
wherein replicating the backup copies of the subscriber specific data to the second instance of the distributed database comprises replicating the backup copies to the standby portion of the second instance under control of the distributed database.

8. The method of claim 7, wherein the first and second CNIs have a group backup association such that a first plurality of subscribers assigned to the first CNI are all backed up to the standby portion of the second instance of the distributed database residing on the second CNI and a second plurality of subscribers assigned to the second CNI are all backed up to the standby portion of the first instance of the distributed database residing on the first CNI.

9. The method of claim 7, wherein multiple subscribers assigned to the first CNI are backed up on a per subscriber basis to the standby portion of the distributed database residing on multiple different ones of the plurality of CNIs.

10. The method of claim 1, further comprising:
transferring a workload associated with processing the subscriber traffic from the first CNI to the second CNI, if the first CNI fails; and
activating a backup for the subscriber stored on the second CNI, if the first CNI fails.

11. The method of claim 10, wherein a third CNI and a fourth CNI are provisioned to perform operations, administration, maintenance or provisioning (“OAMP”) functionality and wherein the third CNI is assigned as an active OAMP manager and the fourth CNI is assigned as a standby OAMP manager, the method further comprising:
changing a status of the fourth CNI from the standby OAMP manager to the active OAMP manager, if the third CNI fails.

12. The method of claim 1, wherein the plurality of CNIs are each assigned a plurality of subscribers and each of the plurality of CNIs process subscriber traffic associated with their corresponding plurality of subscribers, the method further comprising:
monitoring workloads of the plurality of CNIs;
determining whether the workloads are inefficiently distributed amongst the plurality of CNIs; and
redistributing the plurality of subscribers amongst the plurality of CNIs, if the determining determines that the workloads are inefficiently distributed.

13. The method of claim 12, wherein redistributing the plurality of subscribers amongst the plurality of CNIs, if the determining determines that the workloads are inefficiently distributed comprises:
determining which of the plurality of subscribers are idle subscribers;
locking the idle subscribers to temporarily block the subscriber traffic associated with the idle subscribers;
redistributing the idle subscribers amongst the plurality of CNIs while leaving active subscribers assigned to their current CNIs; and
unlocking the idle subscribers after the idle subscribers are redistributed.

14. Machine-readable storage media that provide instructions that, if executed by a machine, will cause the machine to perform operations comprising:
assigning a subscriber of a network service to a first compute node instance (“CNI”) of a plurality of CNIs within a network node interposed between the subscriber and a provider of the network service;
processing subscriber traffic associated with the subscriber at the first CNI;
generating subscriber specific data at the first CNI related to the subscriber traffic; and
backing up the subscriber specific data to a second CNI of the network node, wherein the second CNI is designated as a standby CNI to process the subscriber traffic if the first CNI fails.

15. The machine-readable media of claim 14, wherein the network service includes at least one of an Internet access service, a video-on-demand (“VoD”) service, a voice over Internet protocol (“VoIP”) service, or an Internet Protocol television (“IPTV”) service.

16. The machine-readable media of claim 14, wherein the subscriber traffic comprises original subscriber traffic and wherein processing the subscriber traffic associated with the subscriber at the first CNI comprises:
executing at least one network application related to the network service on the first CNI;
replicating portions of the original subscriber traffic at the network node to generate replicated subscriber traffic;
forwarding the original subscriber traffic towards its destination; and
providing the replicated subscriber traffic to the at least one network application executing on the first CNI.

17. The machine-readable media of claim 14, wherein processing the subscriber traffic associated with the subscriber at the first CNI comprises:
intercepting portions of the subscriber traffic at the network node;
forwarding intercepted portions of the subscriber traffic to the at least one network application executing on the first CNI for processing; and
forwarding the intercepted portions towards their destination after the processing.

18. The machine-readable media of claim 16, wherein the at least one network application includes at least one quality of experience (“QoE”) application for monitoring the subscriber's QoE while using the network service.

19. The machine-readable media of claim 14, wherein backing up the subscriber specific data to the second CNI of the network node comprises:
writing the subscriber specific data to a first instance of a distributed database residing on the first CNI, wherein the distributed database includes a plurality of instances each residing on one of the plurality of CNIs; and
replicating backup copies of the subscriber specific data to a second instance of the distributed database residing on the second CNI.

20. The machine-readable media of claim 19,
wherein each of the plurality of instances of the distributed database includes an active portion and a standby portion,
wherein writing the subscriber specific data to the first instance of the distributed database comprises writing the subscriber specific data to the active portion of the first instance of the distributed database residing on the first CNI, and
wherein replicating the backup copies of the subscriber specific data to the second instance of the distributed database comprises replicating the backup copies to the standby portion of the second instance under control of the distributed database.

21. The machine-readable media of claim 20, wherein the first and second CNIs have a group backup association such that a first plurality of subscribers assigned to the first CNI are all backed up to the standby portion of the second instance of the distributed database residing on the second CNI and a second plurality of subscribers assigned to the second CNI are all backed up to the standby portion of the first instance of the distributed database residing on the first CNI.

22. The machine-readable media of claim 20, wherein multiple subscribers assigned to the first CNI are backed up on a per subscriber basis to the standby portion of the distributed database residing on multiple different ones of the plurality of CNIs.

23. The machine-readable media of claim 14, further providing instructions that, if executed by the machine, will cause the machine to perform further operations, comprising:
transferring a workload associated with processing the subscriber traffic from the first CNI to the second CNI, if the first CNI fails; and
activating a backup for the subscriber stored on the second CNI, if the first CNI fails.

24. The machine-readable media of claim 23, wherein a third CNI and a fourth CNI are provisioned to perform operations, administration, maintenance or provisioning (“OAMP”) functionality and wherein the third CNI is assigned as an active OAMP manager and the fourth CNI is assigned as a standby OAMP manager, the machine-readable storage medium, further providing instructions that, if executed by the machine, will cause the machine to perform further operations, comprising:
changing a status of the fourth CNI from the standby OAMP manager to the active OAMP manager, if the third CNI fails.

25. The machine-readable media of claim 14, wherein the plurality of CNIs are each assigned a plurality of subscribers and each of the plurality of CNIs process subscriber traffic associated with their corresponding plurality of subscribers, the machine-readable storage medium, further providing instructions that, if executed by the machine, will cause the machine to perform further operations, comprising:
monitoring workloads of the plurality of CNIs;
determining whether the workloads are inefficiently distributed amongst the plurality of CNIs; and
redistributing the plurality of subscribers amongst the plurality of CNIs, if the determining determines that the workloads are inefficiently distributed.

26. The machine-readable media of claim 25, wherein redistributing the plurality of subscribers amongst the plurality of CNIs, if the determining determines that the workloads are inefficiently distributed comprises:
determining which of the plurality of subscribers are idle subscribers;
locking the idle subscribers to temporarily block the subscriber traffic associated with the idle subscribers;
redistributing the idle subscribers amongst the plurality of CNIs while leaving active subscribers assigned to their current CNIs; and
unlocking the idle subscribers after the idle subscribers are redistributed.

27. A network node for communicatively coupling between a plurality of subscribers of network services and providers of the network services, the network node comprising a plurality of compute node instances (“CNIs”) and at least one memory unit coupled to one or more of the CNIs, the at least one memory unit providing instructions that, if executed by one or more of the CNIs, will cause the network node to perform operations, comprising:
executing a distributed scheduler on one or more of the CNIs to assign each of the subscribers an active CNI from amongst the plurality of CNIs;
executing network applications on the CNIs to process subscriber traffic associated with each of the subscribers and to generate subscriber specific data on the active CNI assigned to each of the subscribers; and
backing up the subscriber specific data from the active CNI for each of the subscribers to a standby CNI from amongst the plurality of CNIs for each of the subscribers, wherein the active CNI and the standby CNI for a particular subscriber are independent CNIs from amongst the plurality of CNIs.

28. The network node of claim 27, wherein each of the CNIs is assigned as the active CNI for a first portion of the subscribers and assigned as the standby CNI for a second portion of the subscribers.

29. The network node of claim 27, wherein the distributed scheduler determines to which of the plurality of CNIs the subscriber specific data associated with each of the subscribers is backed up.

30. The network node of claim 27, wherein all of the subscribers assigned a single active CNI are backed up as a group to a single standby CNI.

31. The network node of claim 27, wherein the at least one memory unit further provides instructions that, if executed by one or more of the CNIs, will cause the network node to perform further operations, comprising:
activating backups residing on one or more of the plurality of CNIs if a first CNI fails, wherein the backups correspond to a first portion of the subscribers having the first CNI assigned as their active CNI; and
transferring workloads from the first CNI to the one or more of the plurality of CNIs to continue processing the subscriber traffic associated with the first portion of the subscribers.

32. The network node of claim 27, wherein backing up the subscriber specific data from the active CNI for each of the subscribers to the standby CNI for each of the subscribers, comprises:
executing a distributed database having instances on each of the plurality of CNIs, wherein each instance of the distributed database includes an active portion to store the subscriber specific data and a standby portion to store backups of the subscriber specific data; and
distributing copies of the subscriber specific data within the active portion on each of the CNIs to the corresponding standby portions.

33. The network node of claim 32, the network applications write the subscriber specific data into the active portion of the distributed database and the distributed database distributes the copies of the subscriber specific data to the standby portions on other CNIs.

34. The network node of claim 27, wherein the at least one memory unit further provides instructions that, if executed by one or more of the CNIs, will cause the network node to perform further operations, comprising:
executing a global arbitrator to monitor workloads of the plurality of CNIs;
determining whether the workloads are inefficiently distributed amongst the plurality of CNIs; and
executing the distributed scheduler to redistribute the plurality of subscribers amongst the plurality of CNIs, if the determining determines that the workloads are inefficiently distributed.

35. The network node of claim 33, wherein executing the distributed scheduler to redistribute the plurality of subscribers amongst the plurality of CNIs, if the determining determines that the workloads are inefficiently distributed, comprises:
determining which of the subscribers are idle subscribers;
locking the idle subscribers to temporarily block the subscriber traffic associated with the idle subscribers;
redistributing the idle subscribers amongst the plurality of CNIs while leaving active subscribers assigned to their current CNIs; and
unlocking the idle subscribers after the idle subscribers are redistributed.
